(19) United States
(12) Patent Application Publication
(10) Pub. No.: US 2021/0351379 A1
(43) Pub. Date: Nov. 11, 2021

(54) DISPLAY PANEL AND METHOD FOR FABRICATING SAME

(71) Applicant: SHENZHEN CHINA STAR OPTOELECTRONICS SEMICONDUCTOR DISPLAY TECHNOLOGY CO., LTD., Shenzhen (CN)

(72) Inventor: Peng ZHANG, Shenzhen (CN)

(73) Assignee: SHENZHEN CHINA STAR OPTOELECTRONICS SEMICONDUCTOR DISPLAY TECHNOLOGY CO., LTD., Shenzhen (CN)

(21) Appl. No.: 16/625,790

(22) PCT Filed: Nov. 15, 2019
(86) PCT No.: PCT/CN2019/118729

§ 371 Date: Dec. 23, 2019

(30) Foreign Application Priority Data
Nov. 6, 2019 (CN) 201911075040.1

(51) Int. Cl. H01L 51/52; H01L 51/56

(52) U.S. Cl. CPC H01L 51/5265; H01L 51/56; H01L 51/5253

(57) ABSTRACT

A display panel and a method for fabricating the same are provided, comprising: a substrate; at least two light-emitting units of different types disposed over the substrate; and an encapsulation layer. The encapsulation layer comprises a first moisture-blocking layer disposed over the substrate, covering the light-emitting units; a buffer layer disposed over the first moisture-blocking layer, wherein the buffer layer having different thicknesses corresponding to the light-emitting units of different types; and a second moisture-blocking layer disposed over the substrate, covering the buffer layer and the first moisture-blocking layer. The thickness of the buffer layer corresponding to light-emitting units of different types is adjusted to adjust the optical microcavity length of different light-emitting units of different types, thereby improving the device performance of the display panel.

### FIELD OF INVENTION

The present invention relates to a display technology, and more particularly to a display panel and a method for fabricating the same.

### BACKGROUND

An organic light-emitting display (OLED) device is also called an organic electroluminescent display device or an organic light-emitting semiconductor. The working principle of the OLED is that when the power is supplied with an appropriate voltage, holes from an anode and charges from a cathode will be combined in the light-emitting layer, and the excitons (electron-hole pairs) under an excited state are formed by a certain probability under the action of Coulomb force, and the excited state is unstable in the normal environment. The excited excitons recombine and transfer energy to the light-emitting material, causing it to transition from the ground state level to the excited state. Energy of the excited state produces photons and light, and releases light energy through the radiation relaxation process. According to different formulas, lights of red, green and blue are generated to form the RGB three primary colors basic color.

OLED has the advantages of low voltage demands, high power saving efficiency, fast response times, light weights, thin thickness, simple structure, low cost, wide viewing angles, almost infinite contrast, low power consumption and high reaction speeds, and has become one of the most important display technologies for now.

### Technical Problem

Since the organic light-emitting display (OLED) uses organic materials, and the organic materials are particularly sensitive to oxygen and moisture. Reactions may occur to deteriorate the organic material, thereby causing the OLED to have low luminous efficiency and a lowered life. Therefore, it is necessary to encapsulate the OLED to achieve the insulating effects to water vapor and moisture, and improve the performance of the OLED device. Existing OLED packaging methods mainly comprise methods such as dam and fill, face seal, frit, and thin film encapsulation (TFE). Among them, the TFE packaging can be made thinner and bendable, which is especially suitable for flexible OLED packages. The organic layer in the TFE package mainly functions as a buffer layer to reduce stresses and prolong a permeation path of oxygen and moisture. For a top light-emitting device, microcavity effects need to be considered as a key object, it is necessary to adjust a thickness of the organic layer corresponding to different light-emitting units to adjust the microcavity effects for achieving best device performances. Therefore, it is necessary to find a new type of display panel and a method of fabricating the same to achieve the above effects.

### Technical Solution

An object of the present invention is to provide a display panel and a method of fabricating the same that can adjust the optical microcavity length of each of the light-emitting units by changing the thickness of the buffer layer corresponding to the different light-emitting units, thereby improving the device performance of the display panel.

In order to achieve the above object, an embodiment of the present invention provides a display panel comprising: a substrate; at least two light-emitting units of different types disposed over the substrate; and an encapsulation layer. The encapsulation layer comprises a first moisture-blocking layer disposed over the substrate, covering the light-emitting units of different types; a buffer layer disposed over the first moisture-blocking layer, wherein the buffer layer having different thicknesses corresponding to the light-emitting units of different types; and a second moisture-blocking layer disposed over the substrate, covering the buffer layer and the first moisture-blocking layer.

Moreover, the light-emitting units are one of a red light-emitting unit, a green light-emitting unit, and a blue light-emitting unit, and the display panel comprises a red light-emitting unit, a green light-emitting unit, and a blue light-emitting unit, wherein a thickness of the buffer layer corresponding to the red light-emitting unit is less than a thickness of the buffer layer corresponding to the green light-emitting unit, and a thickness of the buffer layer corresponding to the green light-emitting unit is less than a thickness of the buffer layer corresponding to the blue light-emitting unit.

Moreover, materials for fabricating the first moisture-blocking layer and the second moisture-blocking layer both comprise one or more of an oxide of silicon, a nitride of silicon, and an oxide of aluminum.

Moreover, methods for fabricating the first moisture-blocking layer and the second moisture-blocking layer both comprise one or more of a chemical vapor deposition method, an atomic layer deposition method, or a sputtering coating method.

Moreover, the light-emitting units comprise: a first electrode disposed over the substrate; a hole injecting layer disposed over the first electrode; a hole transporting layer disposed over the hole injecting layer; a light-emitting layer disposed over the hole transporting layer; and a second electrode disposed over the light-emitting layer.

Moreover, methods for fabricating the hole injecting layer, the hole transporting layer, and the light-emitting layer comprise an evaporation technique or a printing technique.

Another embodiment of the present invention further provides a method of fabricating a display panel related to the present invention, comprising: providing a substrate; forming at least two light-emitting units of different types over the substrate; and forming an encapsulation layer over the light-emitting units of different types. Forming an encapsulation layer over the light-emitting units of different types comprises forming a first moisture-blocking layer over the substrate, and the first moisture-blocking layer covers the light-emitting units of different types; forming a buffer layer over the first moisture-blocking layer, and the buffer layer has different thicknesses corresponding to different light-emitting units of different types; and forming a second moisture-blocking layer over the substrate, and the second moisture-blocking layer extends and covers the buffer layer and the first moisture-blocking layer.

Moreover, the light-emitting units are one of a red light-emitting unit, a green light-emitting unit, and a blue light-emitting unit, and the display panel comprises a red light-emitting unit, a green light-emitting unit, and a blue light-emitting unit, wherein a thickness of the buffer layer corresponding to the red light-emitting unit is less than a thickness of the buffer layer corresponding to the green light-emitting unit, and a thickness of the buffer layer corresponding to the green light-emitting unit is less than a thickness of the buffer layer corresponding to the blue light-emitting unit.

Moreover, a thickness of the buffer layer corresponding to the red light-emitting unit is less than a thickness of the buffer layer corresponding to the green light-emitting unit, and a thickness of the buffer layer corresponding to the green light-emitting unit is less than a thickness of the buffer layer corresponding to the blue light-emitting unit are fabricated by the following steps: fabricating the buffer layer of a first thickness over the first moisture-blocking layer corresponding to the red light-emitting unit, the green light-emitting unit, and the blue light-emitting unit; fabricating a buffer layer of a second thickness over the buffer layer of the first thickness corresponding to the green light-emitting unit and the blue light-emitting unit; and fabricating a buffer layer of a third thickness over the buffer layer of the second thickness corresponding to of the blue light-emitting unit.

Moreover, a thickness of the buffer layer corresponding to the red light-emitting unit is less than a thickness of the buffer layer corresponding to the green light-emitting unit, and a thickness of the buffer layer corresponding to the green light-emitting unit is less than a thickness of the buffer layer corresponding to the blue light-emitting unit are fabricated by the following steps: fabricating a buffer layer of a first thickness over the first moisture-blocking layer corresponding to the red light-emitting unit; fabricating a buffer layer of a first thickness and a buffer layer of a second thickness over the first moisture-blocking layer corresponding to the green light-emitting unit; and fabricating a buffer layer of a first thickness, a buffer layer of a second thickness, and a buffer layer of a third thickness over the first moisture-blocking layer corresponding to the blue light-emitting unit.

### Advantageous Effects

The present invention relates to a display panel and a method for fabricating the same, comprising: a substrate; at least two light-emitting units of different types disposed over the substrate; and an encapsulation layer. The encapsulation layer comprises a first moisture-blocking layer disposed over the substrate, covering the light-emitting units of different types; a buffer layer disposed over the first moisture-blocking layer, wherein the buffer layer having different thicknesses corresponding to the light-emitting units of different types; and a second moisture-blocking layer disposed over the substrate, covering the buffer layer and the first moisture-blocking layer. The present invention adjusts the thickness of the buffer layer corresponding to light-emitting units of different types, thereby adjusting the optical microcavity length of different light-emitting units of different types, thereby improving the device performance of the display panel.

### BRIEF DESCRIPTION OF DRAWINGS

To detailly explain the technical schemes of the embodiments or existing techniques, drawings that are used to illustrate the embodiments or existing techniques are provided. Apparently, the illustrated embodiments are just a part of those of the present disclosure. It is easy for any person having ordinary skill in the art to obtain other drawings without labor for inventiveness.

FIG. 1 is a structural schematic view of a display panel according to the present invention.

FIG. 2 is a first drawing showing a fabrication step of the display panel of Embodiment 2.

FIG. 3 is a second drawing showing a fabrication step of the display panel of Embodiment 2.

FIG. 4 is a third drawing showing a fabrication step of the display panel of Embodiment 2.

FIG. 5 is a fourth drawing showing a fabrication step of the display panel of Embodiment 2.

FIG. 6 is a fifth drawing showing a fabrication step of the display panel of Embodiment 2.

FIG. 7 is a sixth drawing showing a fabrication step of the display panel of Embodiment 2.

FIG. 8 is a seventh drawing showing a fabrication step of the display panel of Embodiment 2.

FIG. 9 is a first drawing showing a fabrication step of the display panel of Embodiment 3.

FIG. 10 is a second drawing showing a fabrication step of the display panel of Embodiment 3.

FIG. 11 is a third drawing showing a fabrication step of the display panel of Embodiment 3.

FIG. 12 is a fourth drawing showing a fabrication step of the display panel of Embodiment 3.

FIG. 13 is a fifth drawing showing a fabrication step of the display panel of Embodiment 3.

FIG. 14 is a sixth drawing showing a fabrication step of the display panel of Embodiment 3.

Components in the figures are identified as follows:
1, substrate 2, light-emitting unit
3, encapsulation layer 4, mask
21, red light-emitting unit 22, green light-emitting unit
23, blue light-emitting unit
31. first moisture blocking layer, 32 buffer layer
33. second moisture blocking layer
321. buffer layer of a first thickness, 322 buffer layer of a second thickness
323, buffer layer of a third thickness

### DETAILED DESCRIPTION

Please refer to the drawings in the drawings, in which the same reference numerals represent the same components. The following description is based on the specific embodiments of the present invention as illustrated and should not be construed as limiting the specific embodiments that are not described herein.

The directional terms mentioned in the present invention, such as “upper”, “lower”, “before”, “after”, “left”, “right”, “inside”, “outside”, “side”, etc., are only used to show direction in the figures. The directional terms used in the drawings are used to explain and explain the invention and are not intended to limit the scope of the invention.

In the drawings, structurally identical components are denoted by the same reference numerals, and structural or functionally similar components are denoted by like reference numerals. Moreover, the size and thickness of each component shown in the drawings are arbitrarily shown for ease of understanding and description, and the invention does not limit the size and thickness of each component.

When a component is described as “on” another component, the component can be placed directly on the other component; there can also be an intermediate component that is placed on the intermediate component, and the intermediate component is placed on another component. When a component is described as “installed to” or “connected to” another component, it can be understood as “directly” or “connected” or a component is “mounted to” or “connected” through an intermediate component to another component.

### Embodiment 1

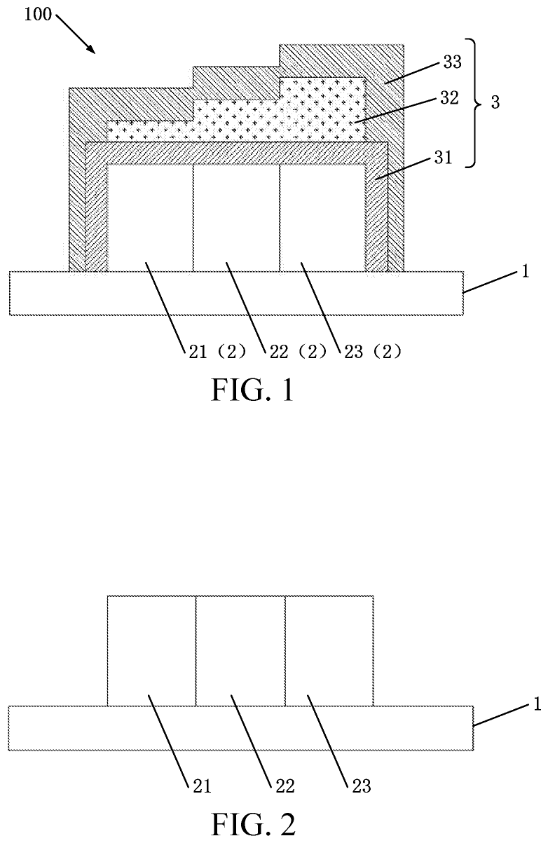

As shown in FIG. 1, a display panel 100 comprises a substrate 1, at least two light-emitting units 2 of different types, and an encapsulation layer 3.

The light-emitting unit 2 is disposed over the substrate 1. The light-emitting units 2 can be divided into one of a red light-emitting unit 21, a green light-emitting unit 22, and a blue light-emitting unit 23. Each of the light-emitting units 2 comprises: a first electrode disposed over the substrate 1; a hole injecting layer disposed over the first electrode; and a hole transporting layer disposed over the space a hole injecting layer; a light-emitting layer disposed over the hole transporting layer; and a second electrode disposed over the light-emitting layer. Methods for fabricating the hole injecting layer, the hole transporting layer, and the light-emitting layer comprises an evaporation technique or a printing technique.

As shown in FIG. 1, the display panel 100 of the present embodiment comprises three types of light-emitting units 2, which are a red light-emitting unit 21, a green light-emitting unit 22, and a blue light-emitting unit 23, respectively.

As shown in FIG. 1, the encapsulation layer 3 comprises a first moisture-blocking layer 31, a buffer layer 32, and a second moisture-blocking layer 33.

The first moisture-blocking layer 31 is disposed over the substrate 1 and covers the light-emitting units 2. The first moisture-blocking layer 31 is fabricated by one or more methods of chemical vapor deposition, atomic layer deposition, or sputtering. Fabrication materials thereof comprises one or more materials of an oxide of silicon, a nitride of silicon, and an oxide of aluminum. Thus, the first moisture-blocking layer 31 can have good blocking performances to moisture and oxygen, preventing the device from aging due to penetration of moisture and oxygen.

The buffer layer 32 is disposed over the first moisture-blocking layer 31, and the buffer layer 32 has different thicknesses corresponding to different light-emitting units 2. Specifically, a thickness of the buffer layer 32 corresponding to the red light-emitting unit 21 is less than a thickness of the buffer layer 32 corresponding to the green light-emitting unit 22, and a thickness of the buffer layer 32 corresponds to the green light-emitting unit 22 is less than the buffer layer 32 corresponds to the blue light-emitting unit 23. Thus, the optical microcavity lengths of the different light-emitting units 2 are adjusted by adjusting the thicknesses of the buffer layers 32 corresponding to the different light-emitting units 2, thereby improving the device performance of the display panel 100.

The second moisture-blocking layer 33 is disposed over the substrate 1 and covers the buffer layer 32 and the first moisture-blocking layer 31. The fabrication method of the second moisture-blocking layer 33 comprises one or more methods of a chemical vapor deposition method, an atomic layer deposition method, or a sputtering coating method. Fabrication materials of the second moisture-blocking layer 33 each comprises one or more materials of an oxide of silicon, a nitride of silicon, and an oxide of aluminum. Therefore, the second moisture-blocking layer 33 can have good performance for blocking moisture and oxygen, preventing the device from aging due to penetration of moisture and oxygen.

### Embodiment 2

This embodiment provides a method for fabricating the display panel 100 according to the present invention, comprising the following steps.

As shown in FIG. 2, a substrate 1 is provided, and a red light-emitting unit 21, a green light-emitting unit 22, and a blue light-emitting unit 23 are formed over the substrate 1.

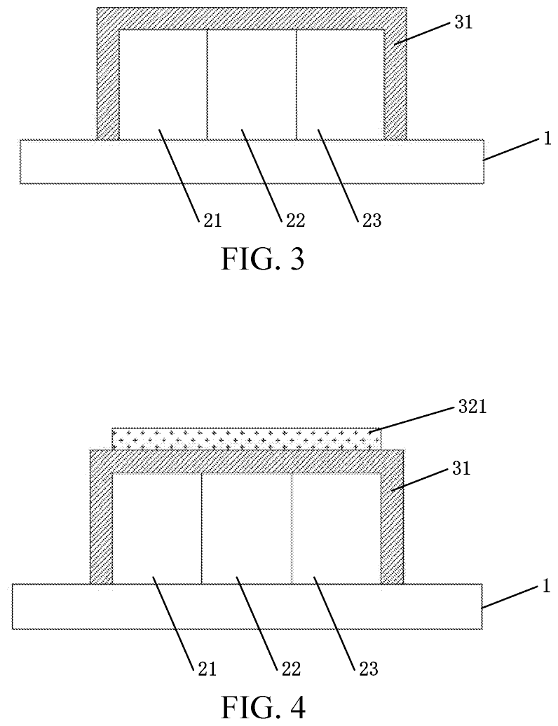

As shown in FIG. 3, a first moisture-blocking layer 31 is formed over the substrate 1, and the first moisture-blocking layer 31 covers the red light-emitting unit 21, the green light-emitting unit 22, and the blue light-emitting unit 23.

As shown in FIG. 4, a buffer layer 321 of a first thickness is fabricated over the first moisture-blocking layer 31 corresponding to the red light-emitting unit 21, the green light-emitting unit 22, and the blue light-emitting unit 23.

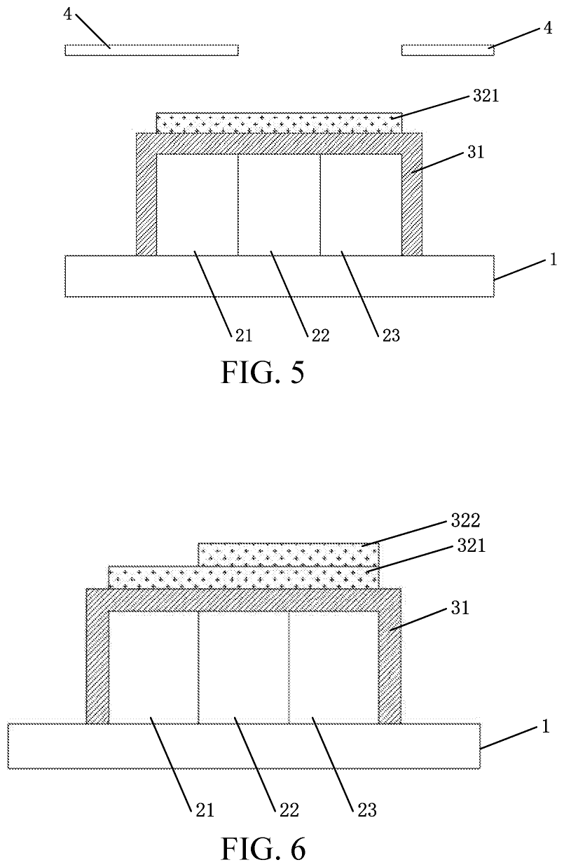

As shown in FIG. 5, regions other than the green light-emitting unit 22 and the blue light-emitting unit 23 are shielded by a mask 4.

As shown in FIG. 6, a buffer layer 322 of a second thickness is fabricated over the buffer layer 321 of the first thickness corresponding to the green light-emitting unit 22 and the blue light-emitting unit 23.

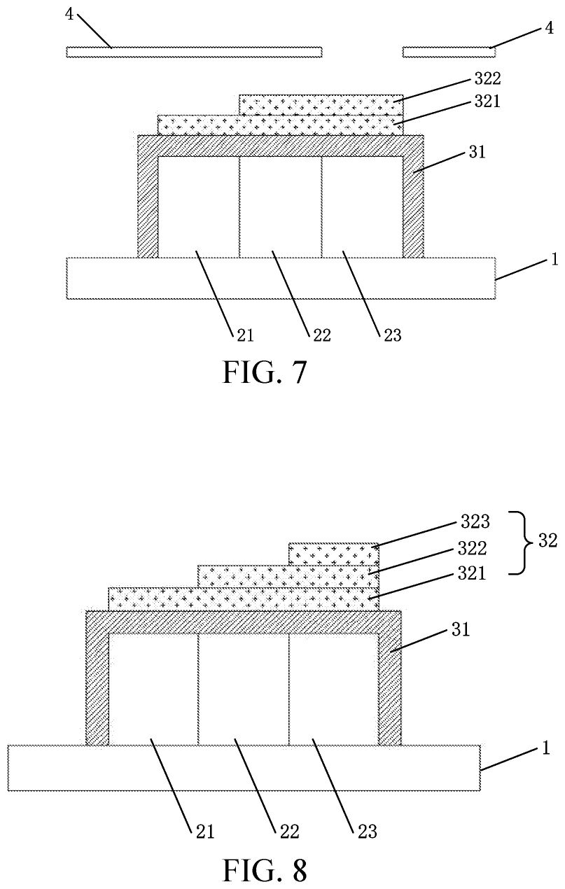

As shown in FIG. 7, the region other than the blue light-emitting unit 23 is shielded by the mask 4.

As shown in FIG. 8, a buffer layer 323 of a third thickness is fabricated over the buffer layer 322 of the second thickness corresponding to the blue light-emitting unit 23. Thus, the buffer layer 321 of the first thickness, the buffer layer 322 of the second thickness, and the buffer layer 323 of the third thickness jointly form the buffer layer 32. The thickness of the buffer layer 32 corresponding to the red light-emitting unit 21 is less than the thickness of the buffer layer 32 corresponding to the green light-emitting unit 22, and the thickness of the buffer layer 32 corresponding to the green light-emitting unit 22 is less than the thickness of the buffer layer 32 corresponds to the blue light-emitting unit 23. Effects of improving the device performance of the display panel by adjusting the thickness of the buffer layer 32 corresponding to the different light-emitting units 2 to adjust the length of the optical microcavities of the different light-emitting units 2 are achieved.

As shown in FIG. 1, the method for fabricating the display panel 100 further comprises: forming a second moisture-blocking layer 33 over the substrate 1, and the second moisture-blocking layer 33 extends and covers the buffer layer 32 and the first moisture-blocking layer 31. Thereby, the first moisture-blocking layer 31, the buffer layer 32, and the second moisture-blocking layer 33 collectively form the encapsulation layer 3, thereby achieving effects of preventing penetration of moisture and oxygen.

### Embodiment 3

The embodiment provides a method for fabricating the display panel 100 according to the present invention, comprising the following steps.

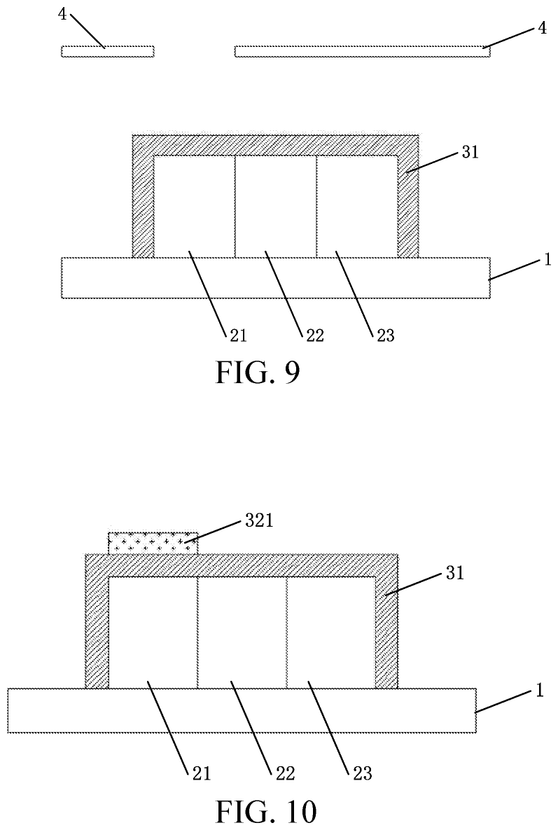

As shown in FIG. 9, a substrate 1 is provided, and a red light-emitting unit 21, a green light-emitting unit 22, and a blue light-emitting unit 23 are formed over the substrate 1. A first moisture-blocking layer 31 is formed over the substrate 1, and the first moisture-blocking layer 31 covers the red light-emitting unit 21, the green light-emitting unit 22, and the blue light-emitting unit 23. Regions other than the red light-emitting unit 21 is shielded by the mask 4.

As shown in FIG. 10, a buffer layer 321 of a first thickness is fabricated over the first moisture-blocking layer 31 corresponding to the red light-emitting unit 21.

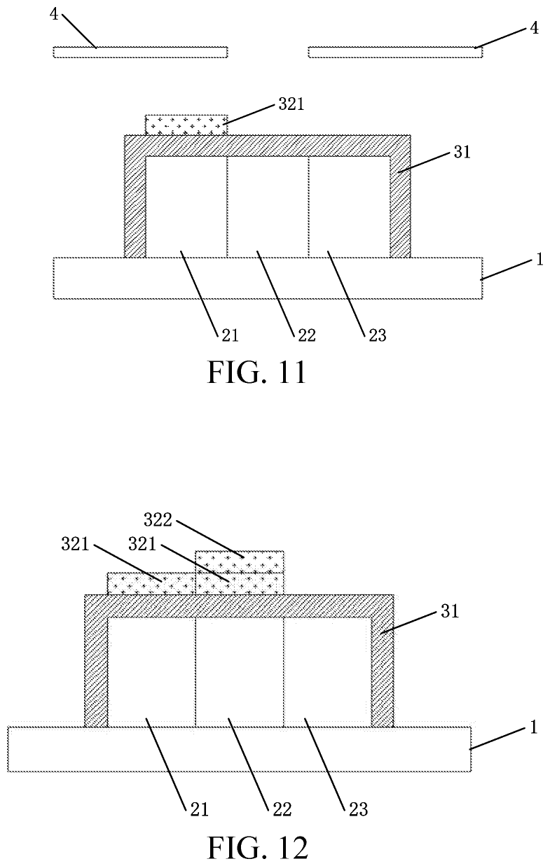

As shown in FIG. 11, regions other than the green light-emitting unit 22 is shielded by the mask 4.

As shown in FIG. 12, a buffer layer 321 of a first thickness and a buffer layer 322 of a second thickness are prepared over the first moisture-blocking layer 31 corresponding to the green light-emitting unit 22.

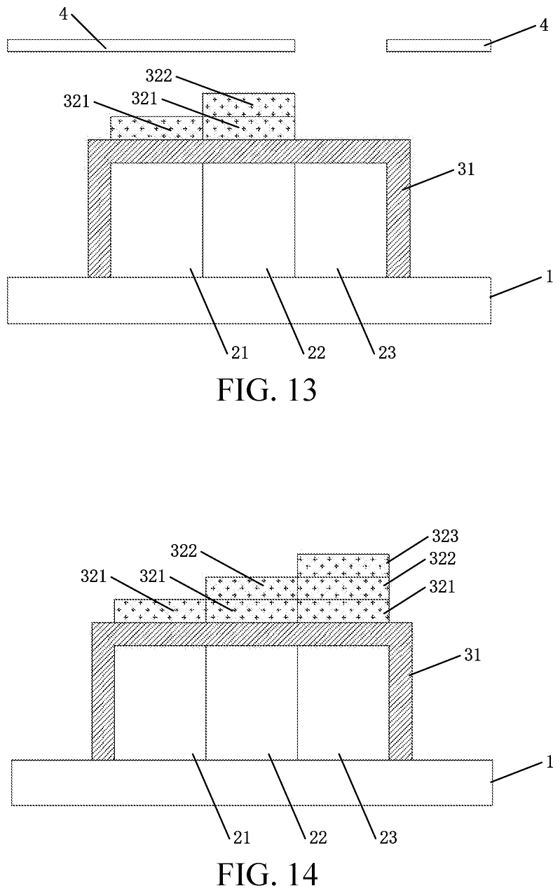

As shown in FIG. 13, regions other than the blue light-emitting unit 23 is blocked by the mask 4.

As shown in FIG. 14, a buffer layer 321 of a first thickness, a buffer layer 322 of a second thickness, and a buffer layer 323 of a third thickness are prepared over the first moisture-blocking layer 31 corresponding to the blue light-emitting unit 23. At this time, the buffer layer 321 of the first thickness corresponding to of the red light-emitting unit 21, the buffer layer 322 of the second thickness corresponding to the green light-emitting unit 22 and the buffer layer 323 of the third thickness corresponding to the blue light-emitting unit 23, and the buffer layer 321 of the first thickness, the buffer layer 322 of the second thickness, and the buffer layer 323 of the third thickness are combined to form the buffer layer 32. The thickness of the buffer layer 32 corresponding to the red light-emitting unit 21 is less than the thickness of the buffer layer 32 corresponding to the green light-emitting unit 22, and the thickness of the buffer layer 32 corresponding to the green light-emitting unit 22 is less than the buffer layer 32 corresponds to the blue light-emitting unit 23. Effects of improving device performances of the display panel by adjusting the thickness of the buffer layer 32 corresponding to the different light-emitting units 2 to adjust the length of the optical microcavities of the different light-emitting units 2 is achieved.

While the present disclosure has been described with the aforementioned preferred embodiments, it is preferable that the above embodiments should not be construed as limiting of the present disclosure. Anyone having ordinary skill in the art can make a variety of modifications and variations without departing from the spirit and scope of the present disclosure as defined by the following claims.

What is claimed is:

1. A display panel, comprising:
a substrate;
at least two light-emitting units of different types disposed over the substrate; and
an encapsulation layer, comprising:
a first moisture-blocking layer disposed over the substrate, covering the light-emitting units of different types;
a buffer layer disposed over the first moisture-blocking layer, wherein the buffer layer having different thicknesses corresponding to the light-emitting units of different types; and
a second moisture-blocking layer disposed over the substrate, covering the buffer layer and the first moisture-blocking layer.

2. The display panel according to claim 1, wherein the light-emitting units are one of a red light-emitting unit, a green light-emitting unit, and a blue light-emitting unit, and the display panel comprises a red light-emitting unit, a green light-emitting unit, and a blue light-emitting unit, wherein a thickness of the buffer layer corresponding to the red light-emitting unit is less than a thickness of the buffer layer corresponding to the green light-emitting unit, and a thickness of the buffer layer corresponding to the green light-emitting unit is less than a thickness of the buffer layer corresponding to the blue light-emitting unit.

3. The display panel according to claim 1, wherein materials for fabricating the first moisture-blocking layer and the second moisture-blocking layer both comprise one or more of an oxide of silicon, a nitride of silicon, and an oxide of aluminum.

4. The display panel according to claim 1, wherein methods for fabricating the first moisture-blocking layer and the second moisture-blocking layer both comprise one or more of a chemical vapor deposition method, an atomic layer deposition method, or a sputtering coating method.

5. The display panel of claim 1, wherein the light-emitting units comprise:
a first electrode disposed over the substrate;
a hole injecting layer disposed over the first electrode;
a hole transporting layer disposed over the hole injecting layer;
a light-emitting layer disposed over the hole transporting layer; and
a second electrode disposed over the light-emitting layer.

6. The display panel according to claim 5, wherein methods for fabricating the hole injecting layer, the hole transporting layer, and the light-emitting layer comprise an evaporation technique or a printing technique.

7. A method of fabricating a display panel according to claim 1, comprising:
providing a substrate;
forming at least two light-emitting units of different types over the substrate; and
forming an encapsulation layer over the light-emitting units of different types, comprising:
forming a first moisture-blocking layer over the substrate, and the first moisture-blocking layer covers the light-emitting units of different types;
forming a buffer layer over the first moisture-blocking layer, and the buffer layer has different thicknesses corresponding to different light-emitting units of different types; and
forming a second moisture-blocking layer over the substrate, and the second moisture-blocking layer extends and covers the buffer layer and the first moisture-blocking layer.

8. The method of fabricating the display panel according to claim 7, wherein the light-emitting units are one of a red light-emitting unit, a green light-emitting unit, and a blue light-emitting unit, and the display panel comprises a red light-emitting unit, a green light-emitting unit, and a blue light-emitting unit, wherein a thickness of the buffer layer corresponding to the red light-emitting unit is less than a thickness of the buffer layer corresponding to the green light-emitting unit, and a thickness of the buffer layer corresponding to the green light-emitting unit is less than a thickness of the buffer layer corresponding to the blue light-emitting unit.

9. The method of fabricating a display panel according to claim 8, wherein a thickness of the buffer layer corresponding to the red light-emitting unit is less than a thickness of the buffer layer corresponding to the green light-emitting unit, and a thickness of the buffer layer corresponding to the green light-emitting unit is less than a thickness of the buffer layer corresponding to the blue light-emitting unit are fabricated by the following steps:
fabricating the buffer layer of a first thickness over the first moisture-blocking layer corresponding to the red light-emitting unit, the green light-emitting unit, and the blue light-emitting unit;
fabricating a buffer layer of a second thickness over the buffer layer of the first thickness corresponding to the green light-emitting unit and the blue light-emitting unit; and
fabricating a buffer layer of a third thickness over the buffer layer of the second thickness corresponding to of the blue light-emitting unit.

10. The method of fabricating a display panel according to claim 8, wherein a thickness of the buffer layer corresponding to the red light-emitting unit is less than a thickness of the buffer layer corresponding to the green light-emitting unit, and a thickness of the buffer layer corresponding to the green light-emitting unit is less than a thickness of the buffer layer corresponding to the blue light-emitting unit are fabricated by the following steps:
fabricating a buffer layer of a first thickness over the first moisture-blocking layer corresponding to the red light-emitting unit;
fabricating a buffer layer of a first thickness and a buffer layer of a second thickness over the first moisture-blocking layer corresponding to the green light-emitting unit; and
fabricating a buffer layer of a first thickness, a buffer layer of a second thickness, and a buffer layer of a third thickness over the first moisture-blocking layer corresponding to the blue light-emitting unit.
